(19) United States
(12) Patent Application Publication
(10) Pub. No.: US 2003/0188679 A1
(43) Pub. Date: Oct. 9, 2003

(54) Powdered mannitol and mannitol-containing compositions

(76) Inventors: Eugen Schwarz, Wasserburg (DE); Karin Maul, Tarrytown, NY (US); Ahmed Al-Ghazawi, Amman (JO)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/362,419

(22) PCT Filed: Aug. 2, 2001
(86) PCT No.: PCT/EP01/08933

(30) Foreign Application Priority Data
Aug. 25, 2000 (EP) 00118106.4

(51) Int. Cl. C30B 1/00

(52) U.S. Cl. 117/2

(57) ABSTRACT

The present invention relates to a process for the production of powdered mannitol with improved flow characteristics for use in inhalation systems, and to mannitol having a particle shape specific for this process. Corresponding active ingredient-containing formulations according to the process according to the invention are also described.

The present invention relates to a process for the production of powdered free flowing mannitol with improved flow characteristics for use in inhalation systems, and to mannitol having a particle shape and improved flowability characteristics specific for this process. The invention additionally embraces various embodiments of the process according to the invention as well as active ingredient-containing formulations containing mannitol for the stated purpose.

The administration of active pharmaceutical ingredients in, inhalation systems has achieved considerable importance in recent time. Formulations which can be employed in these systems must necessarily be convertible into extremely finely atomized aerosols.

This can take place inter alia by using inhalation systems which contain the active ingredients in suitable liquid formulations. However, it is also possible to use inhalation systems which have a two-chamber system in which one chamber is charged with a liquid phase and the other contains a suitable powdered formulation. For administration, the liquid phase and the powder are combined together with one spray actuation.

Owing to the purpose of use, the powdered materials must meet very high quality specifications.

The powder must remain free-flowing in the long term and moreover comprise particles fine enough to reach the lungs satisfactorily. Also desirable are suitable physiological, chemical, physical particulate properties making it possible to employ the powder as carrier material for active pharmaceutical ingredients.

U.S. Pat. No. 5,955,108 discloses the use of spherical microparticles in the form of microcapsules consisting of physiologically tolerated, water-soluble polymeric compounds. The polymers are compounds selected from the group consisting of an amino acid, a polyamino acid and a polypeptide. The microcapsules are obtained from an aqueous solution by spray drying and reacting the precursors. Active ingredients can be linked directly or indirectly to the microcapsules produced in this way. Microcapsules of this type are particularly suitable for delayed release of active ingredients.

However, carrier materials which make rapid release of active ingredient possible are desirable for particular applications. This is necessary, for example with dry powder inhalation formulations. Such formulations are employed for the treatment of acute asthma attacks or for administration of active ingredients through the airways. Dry powder formulations in which the powder particles have sizes below 20 μm are particularly suitable for this form of application.

U.S. Pat. No. 5,898,028 describes, for example, a powder formulation in which the crystalline active ingredient particles have diameters of up to 10 μm. In this case, a wide variety of substances are indicated as suitable carrier materials in the formulations. On the basis of the general physiological tolerability, suitable carriers are regarded as being trehalose, raffinose, mannitol, sorbitol, inositol, sucrose, sodium chloride or sodium citrate, especially since these carriers are also tolerated by diabetics.

To date, lactose has been employed as carrier in particular for crystalline actives and on some occusion for peptide/protein compounds. The particle size is usually between 1 and 25 μm. Another particle size is preferred depending on the active ingredient. Lactose which is used for appropriate formulations is produced by crystallization, followed by grinding and screening to the required particle size. Besides lactose, conventional carrier materials per se are dextrose and sucrose.

Of importance as precondition for possible use as carrier material, besides the physiological tolerability, as already stated, are the particle size and the particle shape because they have a crucial influence on the properties of the powder. It is also of great importance that the particles form no agglomerates and are free-flowing and non-hygroscopic both during production and during storage.

Mannitol is physiologically well tolerated but, although it is not hygroscopic, it cannot be employed in higher concentrations as carrier material in appropriate formulations because of its crystalline form. Accordingly, although the possible use of mannitol for the stated purpose is mentioned in publications, there are no specific examples of the application.

DE 196 15 418 discloses powdered polyol compositions with a mannitol content of more than 90 percent, the particles of which differ considerably from commercially available pure mannitol. The powders obtained by spray drying consist of spherical particles which in turn are composed of microfine crystals. Scanning electron micrographs show that agglomerates of the spherical particles are present in the powder, resulting in a broad particle size distribution in the powder. These polyol compositions are therefore unsuitable for the desired application.

It is the objective of the present invention therefore to provide a powdered free flowing mannitol which, because of its particle shape, improved flowability and good dispersability, can be used in a simple manner as such as carrier material in an inhaler system or in the form of formulations with a pharmaceutical effect.

It is also the objective of the present invention to provide a process by which powdered free flowing mannitol with low-hygroscopicity and good dilution characteristics can be produced in a simple manner.

The objectives are achieved by a process for the production of powdered mannitol for use in a powder inhalation system by

a) producing a solution comprising mannitol in a concentration of from 2 to 70% by weight,

b) spraying the resulting solution into an ascending stream of air in a spray tower or in a fluidised bed dryer at a temperature of from 20 to 400° C., preferably 50-250° C., with the aid of spray nozzles, atomisers or of a multicomponent atomising nozzle which has at least three concentric flow channels each leading to a slit-like orifice, with each slit orifice for spraying a liquid being flanked on each side by a slit orifice for emergence of a gas,

c) fluidizing, drying and collecting the powdered product which is formed,

d) where appropriate recycling a part of the powder which is formed and/or spraying also a solid-containing suspension

e) using water or suitable organic solvents to produce the solution(s) or suspensions

A mannitol-containing solution with a concentration of from 5 to 50% by weight, preferably 5 to 20% by weight, is used to carry out the process.

Particles with a crystal structure specific for the production process are obtained by varying the process parameters of spraying pressure, amount of liquid fed in, slit width of the nozzle, stream of hot air, temperature of the hot air and temperature of the sprayed solution.

The invention therefore relates to a process for obtaining a mannitol which has an apparent density of from 20 to 70 g/100 ml, in particular of 25-50 g/100 ml, and whose particles have a size distribution of 1-200 μm, preferably 20-125 μm.

In a particular embodiment of the process, a mannitol-containing solution and a solid-containing suspension are sprayed together.

A modification within the scope of the invention furthermore comprises spraying mannitol in solution together with at least one active ingredient selected from the group of active ingredients for gene therapy, for treating pain including headaches and migraine, for treating Alzheimer's, cancer, and cytostatics, antiallergics, antidiabetics, antibiotics, bronchodilator, antitussive, antiasthmatic, steroid, sedative, physiologically active peptides/proteins, growth hormones as active ingredients or substances with antiinfectious or antiviral effect in a therapeutically effective dose and, where appropriate, together with flavourings, surfactants, emulsifying agents, antistatic agents, and colours, and formulating as powder mixture for inhaler systems for administration into the lung.

This also means that mannitol and at least one active ingredient may be spray dried together with further additives like surfactants, emulsifiers, solubilizers and others.

Thus particles with a size distribution of 1-20 μm, preferably 1-10 μm are obtained.

A further step in said process may be that the obtained particles, containing at least one active ingredient, are mixed with powdered mannitol prepared in a process according to the invention having a particle size distribution of 1-20 μm.

In modifications of the process, active ingredient-containing solutions can be sprayed both together with the mannitol-containing solution and in succession. Further claims relate to corresponding variations.

The present invention therefore relates in particular to a mannitol produced by the process according to the invention and having a spherical, blackberry-like structure. The present invention furthermore relates to powdered active ingredient-containing mannitol formulations which are produced by the process according to the invention.

It has surprisingly been found by experiments that mannitol can be produced with a uniform suitable particle size distribution in a conventional spray tower when an aqueous mannitol-containing solution is sprayed with the aid of a multicomponent atomizing nozzle which has at least three concentric flow channels each leading to a slit-like orifice, with each slit orifice for spraying a liquid being flanked on each side by a slit orifice for emergence of a gas. A suitable embodiment of such a multicomponent atomizing nozzle is described in the Patent Application DE 197 49 072.

A mannitol with a needle-like crystal structure as fine structure is for example obtained with the aid of this multicomponent atomizing nozzle. In the core structure, these fine crystals are connected together in the form of a so-called blackberry structure. This structure has no sharp edges, as is the case with mannitol types normally obtained by crystallization. It is advantageous that no agglomerates are present in the product in which the particles have a spherical blackberry structure as in known spray-dried types (DE 196 15 418). Compared with conventional powdered mannitol, the mannitol according to the invention has considerably improved flow properties with a particle size in the range 1-200 μm, preferably 20-125 μm. Under suitable conditions, more than 98% of the particles in the mannitol powders obtained are smaller than 25 μm. With an optimal choice of the process parameters it is possible to produce homogeneous products with particle sizes below 17 μm.

Besides the altered, more homogeneous particle structure, the powdered product obtained has an increased apparent bulk density compared with conventional mannitol, which has an apparent density of about 60 g/100 ml with an average particle diameter of about 80 μm.

Owing to the characteristic surface of the particles present in the powder and to the particle size distribution, the products show particularly good fluidizing properties, a better flowability, an excellent dispersibility even after a storage for a long time due to the surface energy characteristics and show improved solubility while having lower hygroscopicity during storage. Due to the high particle porosity and the advantageous surface energy properties the particles have a high loading capacity versus adsorbed active ingredients. At the same time, they showed excellent storage stability. All these advantageous properties are responsible for the improved segregation properties in comparison to known products.

Due to the changed properties these mannitol powders are most suitable for the use in dry powder inhalers, because the advantageous properties stay also during long term storage.

To produce the mannitol powders according to the invention it is possible to employ solutions with a mannitol concentration in the range from 1 to 70% by weight, preferably in the range from 5 to 50% by weight. Solutions with a mannitol content between 8 and 25% by weight are particularly preferably used. Water is normally used as solvent. However, organic solvents are also suitable. In a particular embodiment, however, it is also possible to use supercritical solutions, in which case liquid carbon dioxide or liquid nitrogen are used as solvent. Organic solvents which can be used are polar hydrocarbons selected from the group of mono- to tetrahydric alcohols or of non-ozone-damaging halogenated hydrocarbons.

The produced mannitol-containing solutions can be fed into the system at very low temperatures, at room temperature or at elevated temperature depending on the solvents used and the desired purpose of use.

It is furthermore possible, depending on the desired purpose of use, to spray the solutions under pressure. In general smaller particles are produced when the pressure is set at a higher level. It is possible for the pressure to be varied between 2 and 50 bar per se. The range from 2 to 15 bar is preferably used.

Another influencing variable is the spraying of the prepared solution which may be proceeded by spray nozzles, atomisers or multicomponent atomising nozzles. In case of multicomponent atomising nozzles the size of the droplets formed on emergence varies with the width of the slit orifices, and the eventual particle size depends thereon. This means that the pressure which is set during the atomization, as well as the geometry of the atomizing nozzle but also the consistency and temperature of the solution employed together influence the particle size. It is therefore necessary for a particular application to take account of all three process parameters, but the temperature in the system must not be neglected as a further variable.

The spraying of mannitol solutions can take place at a temperature in the spray dryer in the range from 20 to 400° C., preferably 50-250° C. The chosen temperature in turn depends on the design of the spray-drying system, the residence time, but also the desired particle size and structure, and on the required residual moisture content of the product.

It is possible per se for the process according to the invention to take place in a conventional spray tower in which the described multicomponent atomizing nozzle is incorporated. However, it can also take place in a spray dryer with integrated fluidized bed. It may be advantageous in certain cases for the dryer to have different temperature zones, which ensures that the particles which are formed are dried under conditions which are as mild as possible.

A spray-drying system described in the German Patent Application with the file number P 19927 537.8 has also, inter alia, proved to be particularly suitable. This system is one having a spray-drying unit, a fluidized bed, one or more spraying or atomizing nozzles for liquid media, a powder metering device and a powder recycler with fan. The spray nozzles employed for this purpose are one or more of the abovementioned multicomponent atomizing nozzles. The system is preferably operated without powder recycling.

It has been found that it is possible in the way described not only to spray dry pure mannitol solutions to a powder having the described advantageous properties. It is also possible to spray dry mannitol solutions which contain active pharmaceutical ingredients, resulting in fine-particle powders with the described advantageous particle structure. These formulations can be employed directly in suitable powder inhalation systems.

To produce corresponding formulations it is also possible if required to produce powders with a homogeneous active ingredient content by spraying different solutions together with the aid of the multicomponent atomizing nozzle.

A further variant of the production process for the powder materials consists in spraying previously formed mannitol particles with active ingredient-containing solutions in the spray-drying system. Binding of the active ingredients to the surface of the particles is particularly favoured in this procedure owing to the specific porous surface of the mannitol particles. It is also possible in this case where appropriate for the active ingredient to be brought into conjunction with the mannitol particles under conditions which are milder than would be possible if they were sprayed together.

An additional possibility is for the produced agglomerate-free mannitol powder to be suspended in an active ingredient-containing solution, in which case, however, the mannitol must not either be soluble in the solvent used or prone to stick together, and be subjected to a new spray drying in a suitable manner. In contrast to the procedure described above, in this case the active ingredients are applied not just to the surface. The active ingredients are able to be adsorbed into the mannitol particles. The received powders of an average particle size in the range of 1 to 200, preferably to 125 μm, but particularly in the range of 1 to 20 show the same advantageous properties like the previously prepared products.

It is possible according to the invention for corresponding formulations with mannitol as carrier material to be produced for powder inhalation systems which comprise active ingredients for gene therapy, for treating pain including headaches and migraine, for treating Alzheimer's, cancer, and cytostatics, anti-allergies, antidiabetics, antibiotics, bronchodilator, antitussive, antiasthmatic, steroid, sedative, physiologically active peptides/proteins, growth hormones as active ingredients or substances with antiinfectious or antiviral effect.

In this connection it is possible, with the knowledge of the skilled person, in a simple manner to choose the active ingredient concentrations in the solutions to result in powdered products according to the invention which makes dosage of the active ingredient appropriate for the application possible. Thus formulations may be prepared for the application as single dose or multiple dose dry powder inhaler formulation. These formulations may additionally contain where appropriate, flavourings, colours, surfactants, emulsifiers, solubilizers and other additives.

Mannitol having a particle size distribution of 5 to 100 μm prepared according to the invention may be used as a carrier for the preparation of such formulations. It is also possible to use a product wherein mannitol is co-sprayed with active ingredients containing solution or suspension for dry powder inhaler formulation having a particle size distribution in the range of 1 to 10 μm. Said Mannitol and the latter binary system may be used for the preparation of one powder inhaler formulation. If appropriate, further carrier substances, like carbohydrates or and cellulose, may be added. Suitable polyols are selected from the group erithritol, maltitol, trehalose, sucrose, maltose and raffinose.

It is possible for the skilled person, with the information given and with the state of the art disclosed in the cited patent applications, including the patent applications cited in this text, to produce mannitol-containing powders according to the invention, with variations of the processes described and indicated herein also being possible with the use of other additions. It is possible for the skilled person to implement, as required, different variations of the described system which can be operated in a wide variety of ways' in each case adapted to the required product.

Accordingly, the scope of this invention comprises not only the embodiments of the process specifically described in this application but also modifications thereof which can be carried out in a simple manner, and product formulations obtained by these modifications.

Furthermore, the contents of the cited patent applications, patents and the cited literature are to be regarded as part of the disclosure of the invention in the present description.

### EXPERIMENTS AND RESULTS

The following are merely illustration of the invention and are not in anyway intended to limit it to the disclosed composition, excipients and methods.

Mannitol was tested as a drug carrier for use in DPI formulations using Salbutamol sulphate USP as the model drug substance. The prototype formulations were assessed for homogeneity (%RSD) and % respirable fraction (%RF) using a direct introduction (DI) multistage liquid impinger (MLI) in direct comparison with a standard salbutamol/lactose formulation.

The mannitol formulation was placed on an accelerated stability programme (30° C./60%RH and 40° C./75%RH) along with an equivalent lactose control formulation. The blends were filled into hard gelatin capsules and were assessed for %RF using the MLI with DI and introduction using a “Rotahaler” device.

The results from the stability study showed that the %RF results for the mannitol formulation were significantly better than lactose when freshly prepared and at least equivalent to the lactose formulation results upon storage at accelerated condition.

This in some respects was unexpected as mannitol is inherently non-hygroscopic compared to lactose.

These results are linked to the choice of model drug, since Salbutamol sulphate is a readily soluble drug.

The salbutamol coats the carrier on blending and dissolves and recrystallises on exposure to elevated temperature and humidity storage conditions thereby forming solid bridges between the drug carrier particles, hindering their flow and performance in the MLI. The best results were achieved with mannitol particle sizes in the range of 75-120 μm. The blending with the drug are done using a low energy Turbula mixer.

In summary this means, that in cases where mannitol particles are coated it is an adequate alternative to lactose as a drug carrier. This means also that the advantageous properties of mannitol of being non-hygroscopic compared to lactose are most effective if readily soluble drugs are co-spray dried under mild conditions together with mannitol.

2. Materials Used

2.1 Salbutamol Sulphate

Salbutamol Sulphate USP supplied by Profarmaco, Italy B/N 330912.

Micronised B/N 9911062 and supplied from Dey Laboratories, Napa, USA.

| | | |
|---|---|---|
| Particle Size Specification: | 90% | <10 μm |
| Not Less Than (NLT) | 88% | >1 μm |
| Mass Mean Diameter (MMD) | | =2-4 μm |
| Particle size result: | 90% | <5.48 μm |
| | 90.17% | >1 μm |
| | MMD | =2.53 μm. |

LDH batch number SN/00/E1.

Raw Data in Appendix 3

2.2. Lactose USP

Whey Lactose Regular Fine was supplied by Borculo, UK B/N 720703.

| | | | |
|---|---|---|---|
| % Loss on Drying | 5.15% | (% RSD 0.7) | [SOP |
| PD/A/146, | | | |

| | |
|---|---|
| (Karl Fischer) | Reference PF45/31] |

MMD Particle Size 104.54 μm (%RSD 2.0) (Malvern).

2.3 Mannitol

Several batches of mannitol were provided and are summarised below.

| No. | Mannitol |
|---|---|
| 1 | <32 μm |
| 2 | 20-50 μm |
| 3 | CSD type F |
| 4 | 75-120 μm |
| 5 | <20 μm |
| 6 | <10 μm |

3. Methods

3.1 Differential Scanning Calorimetry (DSC)

| | |
|---|---|
| Equipment: | DSC 2010CE (TA Instruments) |
| Method: | Ramp 10° C./min up to 210° C. / |
| | Aluminium pans with pinhole in |
| | lid / Nitrogen purge 30 |
| | ml/min. 3 runs. |

3.2 Thermo Gravimetric Analysis (TGA)

| | |
|---|---|
| Equipment: | TGA 2050CE (TA Instruments) |
| Method: | Ramp 10° C./min up to 210° C. / |
| | Aluminium pans with no lid / |
| | Nitrogen purge 40 ml/min. 3 |
| | runs. |

3.3 Avalanching/Flow Properties Evaluation

| | |
|---|---|
| Equipment: API | Aeroflow 08030 (Amherst Process |
| | Instruments) |
| Method: | Sample size 50 ml/˜5 g loaded in drum / 1 |
| | rotation per min / runs of 2 |
| | minutes 3 runs. |

3.4 Particle Size Using Image Analysis

Equipment:Leica Image Analysis System (Leica Optical Microscope)

| | |
|---|---|
| Method: | liquid paraffin (25 × 25 |
| | fields) |

3.5 Particle Size Using Laser Diffraction

| | |
|---|---|
| Equipment: | Malvern Mastersizer S, Q Spec Dry |
| | Powder Feeder, V2.18 |
| Method: | 500 mg sample / gate spacing 0.5 cm / |
| | 50% feedrate at 2 bar pressure / 5 |
| | measurements. |

3.6 Electrostatic Charges

| | |
|---|---|
| Equipment: | Faraday Pail 147 System (JC Instruments) |
| Method: | 3 g assay / antistatic boats / reading |
| | after 30 secs. (5 assays). |

3.7 SEM

| | |
|---|---|
| Equipment: | Joel JSM35 SEM |
| Method: | Sample gold coated using Edwards SM300 |
| | sputter coater at 40 mA for 3 mins / |
| | viewed and photographed at defined |
| | kV. |

3.8 Sieving

| | |
|---|---|
| Equipment: | Endecott Octagon 200S sieve |
| | shaker |
| Method: | Sample sieved using defined |
| | mesh sieve |

3.9 Milling

| | |
|---|---|
| Equipment: | Strahlmnehle Air jet mill JMRS |
| Method: | Injector nozzle pressure /air nozzle |
| | pressure / inner funnel setting and |
| | feedrate varied to achieve optimum |
| | results. |

3.10 Salbutamol Sulphate Assay and Content Uniformity (%RSD)

| | |
|---|---|
| Equipment: | HPLC High Presure Liquid |
| | Chromatography |
| Method: | LDH IP5 131 R1 |

3.11 Percentage Respirable Fraction (%RF)

| | |
|---|---|
| Equipment: | Multistage Liquid Impinger (MLI) |
| Method: | LDH QC5 131 R2 / 60 l.min⁻¹ / evacuation |
| | time of 20 secs / 3 assays. |

4.1 Physico-Chemical

All batches of Mannitol used in this evaluation are summarised in Table 1 and the physico-chemical properties of all batches (as defined in Table 1) are summarised in Tables 2-8 and below.

DSC:

A single peak was observed at the melting point with similar values for all batches (167.3 to 169.7° C.) and meet the specifications from Ph Eur 1987 and USP XXII 165 to 169° C.

TGA:

All batches of mannitol gave the same results. The weight loss is insignificant (less than 0.5%), and there were no transitions or loss of water, hence Mannitol appears to be anhydrous.

Avalanching/Flowability Analysis

All batches of Mannitol gave similar results indicating good flow.

Particle Size

The particle size of each of the batches of Mannitol, were measured using two different techniques i.e., laser diffraction (Malvern) and optically (Image analysis). For all results, the particle size observed was in agreement with the batch details.

Static Charge Analysis

Static Charge Analysis indicated a small negative charge associated with all the Mannitol grades. The variability observed using this method is high due to the low charge of the particles (compared to e.g., lactose analysed in same conditions).

SEM

The results indicate visually crystal habit and uniformity. An overall summary would be that particles below 20 μm appear to be spherical, uniform and smooth with evidence of pores, perhaps indicating hollow spheres.

Larger particles tend to be non-spherical but fairly uniform in shape with rough surfaces and evidence of pores. Also with evidence of fines alone or adhering to larger particles.

TABLE 1
Mannitol History

| | Processing | Product Batch |
|---|---|---|
| Description | Details | Description |
| 75-120 μm DMR | — | Mixing Trial |
| CSD type F | Sieved <150 μm | Blend 1 |
| CSD type F | Sieved ≦ 150 μm | Blend 2 (+10% 10 μm |
| | | fines) |
| CSD type F | Sieved ≦ 150 μm | Blend 3 (+10% 20 μm |
| | | fines) |
| CSD type F | Sieved ≦ 150 μm | Blend 4 (+10% 32 μm |
| | | fines) |
| <10 μm, Ringnozzle: | — | Blend 2 |
| 2bar, 0.5 mm | | |
| <20 μm, Rotation | — | Blend 3 |
| nozzle: 4.0bar | | |
| <32 μm, sieved by | — | Blend 4 |
| airjet | | |
| CSD type F | Sieved ≦ 150 μm | Stability batch |
| “As is” | | |
| CSD type F | Sieved <150 μm | Stability batch / |
| “As is” | | repeat |

TABLE 2
Physico-chemical results for Mannitol B/N
000506A

| Test | Result | Comment |
|---|---|---|
| DSC | 3 Runs / Melting point | Complies with USP. |
| | max 168.7° C., 168.2° C., | |
| | 168.2° C. | |
| TGA | 3 Runs / No events, | Complies with USP |
| | <0.5% weight loss. | |
| Aeroflow | 3 Runs / No. of | Represents good flow |
| | avalanches 54, 58 & 47 | |
| | 3 Runs /Mean Time | |
| | between avalanches | |
| | 2.07, 1.0 & 2.5 | |
| Particle | D (v, 0.5) = 49.84 μm | Mean of 5 |
| Size | (% RSD = 0.77) | measurements |
| Malvern | D (v, 0.1) = 10.96 μm | |
| | (% RSD = 2.18) | |
| | D (v, 0.9) = 114.41 μm | |
| | (% RSD = 1.07) | |
| Particle | Mean of 625 readings = | |
| size | 92.08 μm (SD = 33.52) | |
| Microscope | Min = 40.20 μm. Max = | |
| | 176.26 μm. | |
| Static | Mean = −1.0 mV (% RSD = | |
| Charge | 53.62) | |
| SEM | Non spherical | |
| | particles but fairly | |
| | uniform shape. Rough | |
| | surfaces with evidence | |
| | of pores. Also | |
| | evidence of fines both | |
| | alone and adhering to | |
| | larger particles. | |

TABLE 3
Physico-chemical results for Mannitol B/N
000506B (milled)

| Test | Result | Comment |
|---|---|---|
| DSC | 3 Runs / Melting point | Complies with |
| | max 168.6° C., 169.7° C., | USP. |
| | 169.4° C. | |
| TGA | 3 Runs / No events, <0.5% | Complies with |
| | weight loss. | USP |
| Aeroflow | 3 Runs / No. of | Represents |
| | avalanches 81, 64, 75 | good flow |
| | 3 Runs /Mean Time between | |
| | avalanches 1.47, 1.83, | |
| | 1.60 | |
| Particle | D (v, 0.5) = 141.18 μm | Failed Milling |
| Size | (% RSD = 2.01) | Not adequate |
| Malvern | D (v, 0.1) = 31.10 μm (% RSD = | size reduction |
| | 3.61) | |
| | D (v, 0.9) = 265.35 μm | |
| | (% RSD = 1.57) | |
| Particle | Mean of 625 readings = | |
| size | 119.86 μm (SD = 65.35) | |
| Microscope | Min = 42.33 μm. Max = | |
| | 314.05 μm. | |
| Static | Mean = −0.98 mV (% RSD = | |
| Charge | 33.73) | |
| SEM | Non spherical particles | |
| | but fairly uniform shape. | |
| | Rough surfaces with | |
| | evidence of pores. Also | |
| | evidence of fines both | |
| | alone and adhering to | |
| | larger particles. More | |
| | fines c.f. unmilled. | |

TABLE 4
Physico-chemical results for Mannitol B/N
SN/00/F6 (<10 μm)

| Test | Result | Comment |
|---|---|---|
| DSC | 3 Runs / Melting point | Complies with |
| | max 168.6° C., 168.0° C., | USP. |
| | 167.7° C. | |
| TGA | 3 Runs / No events, | Complies with |
| | <0.5% weight loss. | USP |
| Aeroflow | — | |
| Particle | D (v, 0.5) = 6.20 μm (% RSD = | Mean of 5 |
| Size | 1.43) | measurements |
| Malvern | D (v, 0.1) = 2.10 μm (% RSD = | |
| | 2.71) | |
| | D (v, 0.9) = 15.11 μm | |
| | (% RSD = 1.57) | |
| Particle | Mean of 625 readings = | |
| size | 5.84 μm (SD = 1.75) | |
| Microscope | Min = 1.83 μm. Max = | |
| | 10.73 μm. | |
| Static | — | |
| Charge | | |
| SEM | Spherical, smooth | |
| | relatively uniformly | |
| | sized particles | |

TABLE 5
Physico-chemical results for Mannitol B/N
SN/00/F5 (<20 μm)

| Test | Result | Comment |
|---|---|---|
| DSC | 3 Runs / Melting point | Complies with |
| | max 168.3° C., 168.3° C. | USP. |
| | 168.3° C. | |
| TGA | 3 Runs / No events, | Complies with |
| | <0.5% weight loss. | USP |
| Aeroflow | — | |
| Particle | D (v, 0.5) = 14.31 μm | Mean of 5 |
| Size Malvern | (% RSD = 2.55) | measurements |
| | D (v, 0.1) = 3.92 μm (% RSD = | |
| | 2.10) | |
| | D (v, 0.9) = 37.02 μm | |
| | (% RSD = 2.85) | |
| Particle | Mean of 625 readings = | |
| size | 15.26 μm (SD = 4.46) | |
| Microscope | Min = 0.41 μm. Max = | |
| | 25.93 μm. | |
| Static | — | |
| Charge | | |
| SEM | Spherical, evidence of | |
| | pores /hollow spheres | |
| | with crystalline walls | |

TABLE 6
Physico-chemical results for Mannitol B/N
SN/00/C2 (<32 μm)

| Test | Result | Comment |
|---|---|---|
| DSC | — | |
| TGA | — | |
| Aeroflow | — | |
| Particle | D (v, 0.5) = 19.92 μm (% RSD = | Mean of 5 |
| Size Malvern | 0.42) | measurements |
| | D (v, 0.1) = 6.58 μm (% RSD = | |
| | 1.06) | |
| | D (v, 0.9) = 35.79 μm (% RSD = | |
| | 0.21) | |
| Particle | Mean of 625 readings = | |
| size | 19.88 μm (SD = 6.53) | |
| Microscope | Min = 9.33. Max = | |
| | 26.10 μm. | |
| Static | — | |
| Charge | | |
| SEM | Non spherical particles | |
| | but fairly uniform shape. | |
| | Rough surfaces with | |
| | evidence of pores, | |
| | approximately 0.5 μm | |
| | diameter. Also evidence | |
| | of fines both alone and | |
| | adhering to larger | |
| | particles. More fines | |
| | c.f. unmilled. | |

TABLE 7
Physico-chemical results for Mannitol B/N
000804A

| Test | Result | Comment |
|---|---|---|
| DSC | 3 Runs / Melting point max | Complies with |
| | 167.9° C., 167.5° C., 167.3° C. | USP. |
| TGA | 3 Runs / No events, <0.5% | Complies with |
| | weight loss. | USP |
| Aeroflow | 3 Runs / No. of avalanches | Represents |
| | 61, 61, 60 | good flow |
| | 3 Runs /Mean Time between | |
| | avalanches 1.93, 1.91, | |
| | 1.96 | |
| Particle | D (v, 0.5) = 55.45 μm (% RSD = | Mean of 5 |
| Size | 1.23) | measurements |
| Malvern | D (v, 0.1) = 11.79 μm (% RSD = | |
| | 1.61) | |
| | D (v, 0.9) = 118.13 μm (% RSD = | |
| | 1.03) | |
| Particle | Mean of 625 readings = | |
| size | 39.33 μm (SD = 23.69) | |
| Microscope | Min = 5.59 μm. Max = | |
| | 160.22 μm. | |
| Static | Mean = −0.93 mV (% RSD = | |
| Charge | 32.89) | |
| SEM | Non spherical particles | |
| | but fairly uniform shape. | |
| | Rough surfaces with | |
| | evidence of pores | |

4.2 Mixing Trial

The current work uses blend batch sizes of 1 to 2 kg. Target results are assay (theory±5%), %RSD≦5 and %RF>lactose control result).

Formulation:

| Material | % w/w |
|---|---|
| Salbutamol | 4.02* |
| sulphate | |
| Mannitol | 95.98 |

*Equivalent to 3.33% of salbutamol base.

TABLE 8
Mixing Trial to confirm scale-up process for
1 to 2 kg batch size

| Batch Size | 500 g | 1 kg | | |
|---|---|---|---|---|
| Mannitol | | | | |
| B/N | | | | |
| Mannitol | 75-120 μm | 75-120 μm | | |
| Particle | | | | |
| size | | | | |
| Mixer | Turbula | PP1 | | |
| Mixer Type | Tumble | High shear mixer | | |
| | blender | | | |
| Mixing | medium | 3000 rpm, no | | |
| speed | speed | chopper | | |
| Mixing time | 20 mins | 7.5 mins | 15 mins | 22.5 mins |
| **Assay | 3.72 | 4.14 | 3.92 | 3.83 |
| % w/w | | | | |
| ** % RSD | 4.32 | 1.16 | 0.55 | 0.74 |
| ** % RF | 47 | — | 27 | — |

| | | |
|---|---|---|
| Con- | Optimum mixing | 3000 rpm, no |
| clusion | conditions | chopper, |
| | | 20 mins |

Conclusion:

Generation of comparable assay and %RSD results are defined as the criteria for successful mixing/scale. The results indicate that optimum homogeneity results were obtained using the defined mixing speed (3000 rpm, no chopper), for 15 mins. The result for %RF of the 1 kg batch was lower than the 500 g batch. This is monitored in the blending trials.

4.3 Blending Trials

4.3 Blending Trials

The objective of this section of the work was to investigate the effect of different mannitol batches with different physico-chemical properties on the %RSD and %RF and compare to a control lactose, all using the standard formulation and process conditions as defined in the mixing trial The main difference in the mannitol used is the particle size (Table 9). Target results are assay (theory±5%), %RSD≦5 and %RF≧lactose control result. The results are given in Table 10.

TABLE 9

| | 1 | | | | | |
|---|---|---|---|---|---|---|
| No.: | (comp.) | 2 | 3 | 4 | 5 | 6 |
| Salbutamol | 4.02% | 4.02 | 4.02 | 4.02 | 4.02 | 4.02 |
| sulphate* | | | | | | |
| Lactose | 95.98% | | | | | |
| <200 μm | | | | | | |
| Mannitol | | 95.98 | 85.98 | 85.98 | 85.98 | |
| 75-120 μm | | | | | | |
| Mannitol | | | | | | 95.98 |
| 75-120 μm | | | | | | |
| Mannitol | | | 10.00 | | | |
| <10 μm | | | | | | |
| Mannitol | | | | 10.00 | | |
| <20 μm | | | | | | |
| Mannitol | | | | | 10.00 | |
| <32 μm | | | | | | |
| Batch Size | 1.0 kg | 1.0 kg | 1.0 kg | 1.0 kg | 1.0 kg | 2.0 kg |
| Mixing | Yes | Yes | Yes | Yes | Yes | Yes |
| Conditions: | | | | | | |
| PPI/3000 rpm/ | | | | | | |
| no | | | | | | |
| chopper | | | | | | |
| /20 min | | | | | | |

TABLE 10
The Assay, % RSD and % RF results for the
above formulations

| | | | % RF** |
|---|---|---|---|
| No.: | Assay** | % RSD** | (mean of 3) |
| 1 (comp.) | 3.89 | 2.43 | 44 |
| 2 | 3.83 | 9.58 | 45 |
| 3 | 4.29 | 1.02 | 41 |
| 4 | 5.32 | 4.10 | 31 |
| 5 | 4.06 | 5.42 | 37 |
| 6 | 4.06 | 4.17 | 44 |

Conclusions:

The inclusion of fines is offering no advantage especially with regard to the %RF and compared to the lactose control batch (2). This conclusion is further the particle size analysis data for Mannitol, which is shown to contain 10% particles <10.96 μm, 20.88%<22.49 μm and 29.42%<30.53 μm. Hence it was decided to use formulation No. 2. It was decided to place this formulation on stability and compare to a lactose control batch.

4.4 Stability Trial

A stability trial was initiated to cover the following samples (Table 11).

The blends as defined from the blending trials were filled into capsules prior to placing on stability. The summary stability protocol details are as defined in Table 12 and the results are summarised in Table 13.

TABLE 11

| Material | | |
|---|---|---|
| Salbutamol | 4.02% | 4.02% |
| sulphate | | |
| Lactose <200 μm | | 95.98% |
| Mannitol 75- | 95.98% | |
| 120 μm | | |
| Hard Gelatin | Size 3 | Size 3 |
| Capsules | | |
| Blend Batch | 2.0 kg | 2.0 kg |
| Size | | |
| Capsule fill | 30.0 mg | 30.0 mg |
| weight | | |

TABLE 12
Summary Stability Protocol Details

| | 40° C. / 75% RH | 25° C. / 60% RH |
|---|---|---|
| t = 0 | % RF* | % RF* |
| t = 1w | % RF* | — |
| t = 4w | — | % RF* |

*% RF was determined both by Direct Introduction (DI) into the MLI (as for all previous results) and by Rotahaler Device (RD).

TABLE 13
results of the Stability Programme

| | Mannitol | | lactose | |
|---|---|---|---|---|
| | % RF* (DI) | % RF* (RD) | % RF* (DI) | % RF* (RD) |
| t = 0 (initial) | 33 | 27 | 22 | 18 |
| t = 1w (40/75) | 8 | 8 | 8 | 8 |
| t = 4w (25/60) | 28 | 21 | 31 | 20 |

The %RF results using DI are generally higher than when using the RD. Both of the initial results for mannitol are higher than for lactose but this is not maintained throughout the study.

The summary conclusion must be that the %RF for formulations containing mannitol were significantly better than the control lactose when freshly prepared and at least equivalent in performance with regard to %RF throughout the study.

1. Process for the production of powdered free flowing mannitol for use in a powder inhaler, characterized by
a) producing a solution comprising mannitol in a concentration of from 2 to 70% by weight,
b) spraying the resulting solution into an ascending stream of air in a spray tower or in a fluidised bed dryer at a temperature of from 20 to 400° C. with the aid of spray nozzles, atomisers or of a multicomponent atomizing nozzle which has at least three concentric flow channels each leading to a slit-like orifice, with each slit orifice for spraying a liquid being flanked on each side by a slit orifice for emergence of a gas,
c) fluidizing, drying and collecting the powdered product which is formed,
d) where appropriate recycling a part of the powder which is formed and/or spraying also a solid-containing suspension
e) using water or suitable organic solvents to produce the solution(s) or suspensions.

2. Process according to claim 1, characterized in that a mannitol-containing solution with a concentration of from 5 to 50% by weight, preferably 5 to 20% by weight, is used.

3. Process according to claims 1 and 2, characterized in that particles sizes and crystal stucture are changed by varying the process parameters of spraying pressure, amount of liquid fed in, slit width of the nozzle, stream of hot air, temperature of the hot air and temperature of the sprayed solution.

4. Process according to claims 1 to 3, characterized in that a product which has an apparent density of from 20 to 70 g/100 ml in which the particles have a size distribution of 1-200, preferably 20-125, μm is obtained.

5. Process according to claims 1 to 4, characterized in that a product with an apparent density of 25-50 g/100 ml is obtained.

6. Process according to claims 1 to 3, characterized in that a mannitol-containing solution and a solid-containing suspension are sprayed together.

7. Process according to claims 1 to 3, characterised in that mannitol in solution is sprayed together with at least one active ingredient selected from the group of active ingredients for gene therapy, for treating pain including headaches and migraine, for treating Alzheimer's, cancer, and cytostatics, anti-allergics, antidiabetics, antibiotics, bronchodilator, antitussive, antiasthmatic, steroid, sedative, physiologically active peptides/proteins, growth hormones as active ingredients or substances with antiinfectious or antiviral effect, in a therapeutically effective dose, and, where appropriate, together with flavourings surfactants, emulsifying agents, antistatic agents, and colours, and is formulated as powdered mixture for inhaler systems for administration into the lung.

8. Process according to claim 6 and/or 7, characterised in that particles with a size distribution of 1-20 μm, preferably 1-10 μm are obtained.

9. Process according to claims 6 to 8, characterised in that the obtained particles containing at least one active ingredient are mixed with powdered mannitol prepared in a process according to claims 1 to 5 having a particle size distribution of 1-20 μm.

10. Process according to claims 1 to 3, characterized in that a mannitol-containing solution is sprayed and previously formed particles are sprayed with a solution containing at least one active ingredient selected from the group of active ingredients for gene therapy for treating pain including headaches and migraine, for treating Alzheimer's, cancer, and cytostatics, antiallergics, antidiabetics, antibiotics, bronchodilator, antitussive, antiasthmatic, steroid, sedative, physiologically active peptides/proteins, growth hormones as active ingredients or substances with antiinfectious or antiviral effect, in a therapeutically effective dose.

11. Process according to claims 1-3, characterized in that the resulting powder is suspended in an active ingredient-containing solution, and the resulting suspension is spray dried again.

12. Process according to claims 1-3, characterized in that a mannitol-containing solution is sprayed and dried at the same time as an active ingredient-containing solution.

13. Mannitol, produced by a process according to claims 1-5, having a blackberry-like structure.

14. Use of the powdered product produced by a process according to claims 1 to 5 in dry form in an inhaler.

15. Powdered active ingredient-containing formulation produced by a process according to claims 6 to 12.

16. Mixture of mannitol according to claim 13 and active ingredients in which the particle size distribution is in the range of 1 to 20 μm, most preferably in the range of 1 to 10 μm.

17. Use of mixtures according to claim 16 as single dose or multiple dose dry powder inhaler formulations for gene therapy, for treating pain including headaches and migraine, for treating Alzheimer's, cancer, and cytostatics, antiallergics, antidiabetics, antibiotics, bronchodilator, antitussive, antiasthmatic, steroid, sedative, physiologically active peptides/proteins, growth hormones as active ingredients or substances with antiinfectious or antiviral effect, in a therapeutically effective dose, and, where appropriate, together with flavourings and colours, and is formulated as powdered mixture for inhaler systems for administration into the lung.

18. Use of mannitol produced by a process according to claims 1 to 12 as a carrier having a particle size distribution in the range of 5 to 100 μm or/and as a binary mixture co-sprayed with active ingredients containing solution or suspension for dry powder inhaler formulation having a particle size distribution in the range of 1 to 10 μm.

19. Use of mannitol produced by a process according to claims 1 to 12 having a particle size distribution in the range of 1 to 10 μm mixed with active ingredients having a particle size distribution in the same range in single dose or multiple dose dry powder inhalation formulations.

20. Carrier for dry powder inhalation formulations containing mannitol produced by a process according to claims 1 to 12. Carrier according to claims 20 to 21 containing at least one carbohdrate and/or cellulose.

21. Carrier for dry powder inhalation according to claim 20 with at least one polyol selected from the group erithritol, maltitol, trehalose, sucrose, maltose, lactitol and raffinose.

22. Carrier according to claims 20 to 21 containing at least one carbohdrate and/or cellulose.
